(19) United States
(12) Patent Application Publication
(10) Pub. No.: US 2017/0077156 A1
(43) Pub. Date: Mar. 16, 2017

(54) SOLID STATE IMAGING ELEMENT AND MANUFACTURING METHOD THEREOF, AND ELECTRONIC APPARATUS

(71) Applicant: SEIKO EPSON CORPORATION, Tokyo (JP)

(72) Inventors: Mitsuo SEKISAWA, Sakata-shi (JP); Kazunobu KUWAZAWA, Sakata-shi (JP); Noriyuki NAKAMURA, Sakata-shi (JP); Takehiro ENDO, Sakata-shi (JP)

(73) Assignee: SEIKO EPSON CORPORATION, Tokyo (JP)

(21) Appl. No.: 15/255,976

(22) Filed: Sep. 2, 2016

(30) Foreign Application Priority Data
Sep. 10, 2015 (JP) 2015-178231

(51) Int. Cl. H01L 27/146

(52) U.S. Cl. CPC H01L 27/14616; H01L 27/14689

(57) ABSTRACT

A solid state imaging element according to the invention includes: a semiconductor layer of a first conductivity type; a gate insulation film on the semiconductor layer; a gate electrode on the gate insulation film; a first impurity region of a second conductivity type in the semiconductor layer and in a region outside the gate electrode on a first end portion side; a second impurity region of the second conductivity type in the semiconductor layer and in a region outside the gate electrode on a second end portion side that is opposite to the first end portion of the gate electrode; and a third impurity region of the first conductivity type over the second impurity region in the semiconductor layer at a position separate from the second end portion of the gate electrode as viewed in plan view, and is in contact with the second impurity region.

### BACKGROUND

1. Technical Field

The present invention relates to a solid state imaging element and a manufacturing method thereof. Furthermore, the invention relates to an electronic apparatus using such a solid state imaging element.

2. Related Art

CCDs have been used as a major solid state imaging element in the past, but significant development has been made on CMOS sensors that can be driven at a low voltage and on which peripheral circuits can be mounted. As a result of taking measures in a manufacturing process such as a complete transfer technique and a dark current prevention structure and measures against noise in circuit techniques such as CDS (correlated double sampling), CMOS sensors have been improved and grown as a device surpassing that of CCDs in terms of both quality and quantity, and are now recognized as having image quality equal to that of CCDs. Such a significant advancement of CMOS sensors was made possible by a significant improvement in image quality, and an improvement in charge transfer technique was one of the improvement factors.

As a related technique, JP-A-5-121459 (paragraphs [0009] to [0012], and FIGS. 1 and 2) discloses a solid state imaging device including a FD (floating diffusion) amplifier that does not generate reset noise. The solid state imaging device includes a FD amplifier type charge detection portion including a diffusion region of a second conductivity type formed on a semiconductor layer of a first conductivity type, a potential barrier forming gate electrode provided adjacent to the diffusion region, a final gate electrode of a charge transfer device provided adjacent to the potential barrier forming gate electrode, a resetting MOS transistor for resetting the diffusion region formed so as to have the diffusion region as a source electrode, and a source follower circuit for detecting the potential of the diffusion region, wherein the diffusion region is formed so as to have a high impurity concentration at a center portion thereof and a low impurity concentration at end portions, and a diffusion region of the first conductivity type is formed on the center portion of the diffusion region.

According to JP-A-5-121459 (paragraphs [0009] to [0012], and FIGS. 1 and 2), a diffusion layer of the first conductivity type having a high concentration is formed on the diffusion region of the second conductivity type that forms a floating diffusion. Accordingly, if the resetting transistor is turned on, the diffusion layer is completely depleted, and signal charges transferred from an image capturing portion flow into the floating diffusion and are completely transferred to the drain of the resetting transistor. If the resetting transistor is turned off, because the potential is in a floating state, change in potential at the time of reset operation does not occur, and thus reset noise is not generated.

However, when the diffusion layer (pinning layer) of the first conductivity type having a high concentration is formed on the diffusion region of the second conductivity type to which signal charges are transferred from a photodiode, a potential barrier may be formed in the transfer path for transferring signal charges from the photodiode, causing a transfer failure.

### SUMMARY

An advantage of some aspects of the invention provides a solid state imaging element that can reduce dark current generated by residual charges in an impurity region to which signal charges are transferred from a photodiode and reduce transfer failure by suppressing the generation of a potential barrier in a transfer path for transferring the signal charges. Also, an advantage of some aspects of the invention is that an electronic apparatus or the like using such a solid state imaging element is provided.

A solid state imaging element according to a first aspect of the invention includes: a semiconductor layer of a first conductivity type; a gate insulation film that is located on the semiconductor layer; a gate electrode that is located on the gate insulation film; a first impurity region of a second conductivity type that is located in the semiconductor layer and is located, as viewed in plan view, at least in a region outside the gate electrode on a first end portion side; a second impurity region of the second conductivity type that is located in the semiconductor layer and is located, as viewed in plan view, at least in a region outside the gate electrode on a second end portion side that is opposite to the first end portion of the gate electrode; and a third impurity region of the first conductivity type that is located in an upper portion of the second impurity region in the semiconductor layer at a position separate from the second end portion of the gate electrode as viewed in plan view, and is in contact with the second impurity region.

According to the first aspect of the invention, by providing the third impurity region in an upper portion of the second impurity region to which signal charges are transferred from the first impurity region constituting a photodiode, it is possible to reduce dark current caused by residual charges in the second impurity region. In addition, since the third impurity region is separate from the second end portion of the gate electrode as viewed in plan view, it is possible to reduce a transfer failure by suppressing the generation of a potential barrier in the transfer path for transferring signal charges.

Here, it is desirable that the third impurity region is, as viewed in plan view, separate from the second end portion of the gate electrode in a direction that is approximately orthogonal to the second end portion by 1/6 or more of a length of the gate electrode. In this case, the effect of suppressing the generation of a potential barrier increases.

An electronic apparatus according to a second aspect of the invention includes any of the aforementioned solid state imaging elements. According to the second aspect of the invention, by using a solid state imaging element in which dark current caused by residual charges in an impurity region to which signal charges are transferred from a photodiode is reduced, and in addition, a transfer failure is reduced by suppressing the generation of a potential barrier in the transfer path for transferring signal charges, an electronic apparatus in which the quality of image data obtained by capturing an image of a subject is improved can be provided.

A method of manufacturing a solid state imaging element according to a third aspect of the invention includes: (a) implanting impurity ions of a second conductivity type into a semiconductor layer of a first conductivity type by using a first photoresist as a mask so as to form a first impurity region of the second conductivity type in the semiconductor layer; (b) implanting impurity ions of the second conductivity type into the semiconductor layer by using a second photoresist as a mask so as to form a second impurity region of the second conductivity type in the semiconductor layer; (c) forming a gate electrode on the semiconductor layer via a gate insulation film, the gate electrode having a first end portion on the first impurity region side and a second end portion on the second impurity region side; and (d) implanting impurity ions of the first conductivity type obliquely into the semiconductor layer by using the gate electrode and a third photoresist as a mask so as to form a third impurity region of the first conductivity type, the third impurity region being located in an upper portion of the second impurity region in the semiconductor layer at a position separate from the second end portion of the gate electrode as viewed in plan view, and being in contact with the second impurity region.

Also, a method of manufacturing a solid state imaging element according to a fourth aspect of the invention includes: (a) implanting impurity ions of a second conductivity type into a semiconductor layer of a first conductivity type by using a first photoresist as a mask so as to form a first impurity region of the second conductivity type in the semiconductor layer; (b) forming a gate electrode on the semiconductor layer via a gate insulation film, the gate electrode having a first end portion on the first impurity region side; (c) implanting impurity ions of the second conductivity type into the semiconductor layer by using the gate electrode and a second photoresist as a mask so as to form a second impurity region of the second conductivity type that is located in the semiconductor layer and is located, as viewed in plan view, in a region outside the gate electrode on a second end portion side that is opposite to the first end portion of the gate electrode; and (d) implanting impurity ions of the first conductivity type obliquely into the semiconductor layer by using the gate electrode and a third photoresist as a mask so as to form a third impurity region of the first conductivity type, the third impurity region being located in an upper portion of the second impurity region in the semiconductor layer at a position separate from the second end portion of the gate electrode as viewed in plan view, and being in contact with the second impurity region.

According to the third or fourth aspect of the invention, by forming the third impurity region in an upper portion of the second impurity region to which signal charges are transferred from the first impurity region constituting a photodiode, it is possible to reduce dark current caused by residual charges in the second impurity region. In addition, since the third impurity region is formed so as to be separate from the second end portion of the gate electrode as viewed in plan view, it is possible to reduce a transfer failure by suppressing the generation of a potential barrier in the transfer path for transferring signal charges.

In the specification of the present application, the semiconductor layer refers to a semiconductor substrate, a well formed in a semiconductor substrate, or an epitaxial layer formed on a semiconductor substrate. The first conductivity type may be P-type, and the second conductivity type may be N-type. Alternatively, the first conductivity type may be N-type, and the second conductivity type may be P-type.

### BRIEF DESCRIPTION OF THE DRAWINGS

The invention will be described with reference to the accompanying drawings, wherein like numbers reference like elements.

FIGS. 1A to 1C are diagrams showing a solid state imaging element according to one embodiment of the invention.

FIGS. 2A to 2F are diagrams illustrating the steps of a method of manufacturing the solid state imaging element shown in FIGS. 1A to 1C.

FIGS. 3A and 3B are diagrams showing a solid state imaging element according to a comparative example and the state of potential thereof.

FIGS. 4A and 4B are diagrams showing the solid state imaging element according to one embodiment and the state of potential thereof.

FIG. 5 is a block diagram illustrating an exemplary configuration of an electronic apparatus according to one embodiment.

### DESCRIPTION OF EXEMPLARY EMBODIMENTS

Hereinafter, an embodiment of the invention will be described in detail with reference to the drawings. The same constituent elements are given the same reference numerals, and a redundant description is omitted.

Solid State Imaging Element

A solid state imaging element that is driven at a low voltage will be described in the following embodiment. As the semiconductor substrates on which the solid state imaging elements are formed, it is possible to use N-type semiconductor substrates or P-type semiconductor substrates. However, the following description will be given taking, as an example, cases where an N-type silicon substrate is used.

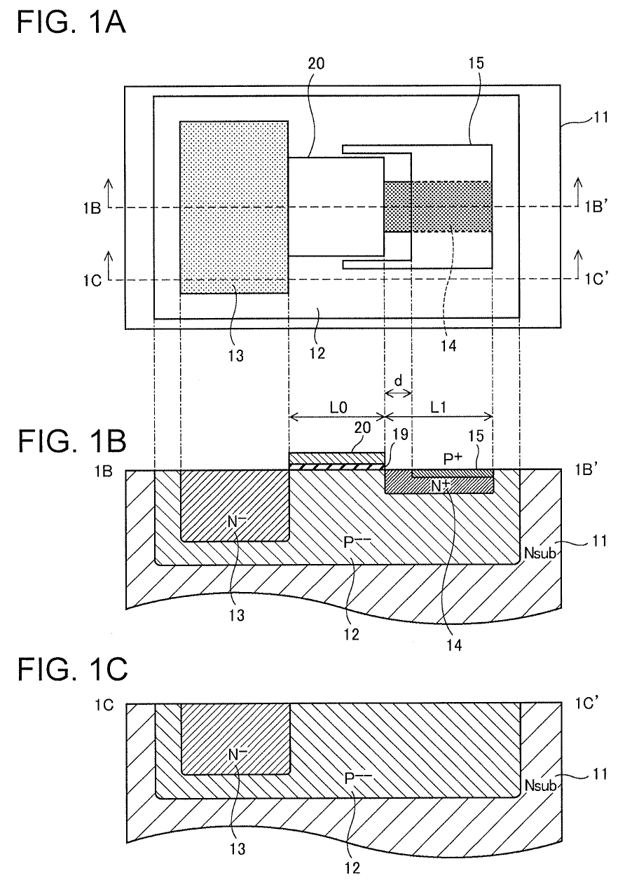

FIGS. 1A to 1C are diagrams showing a solid state imaging element according to one embodiment of the invention. FIG. 1A is a plan view, FIG. 1B is a cross-sectional view taken along line 1B-1B′ shown in FIG. 1A, and FIG. 1C is a cross-sectional view taken along line 1C-1C′ shown in FIG. 1A.

The solid state imaging element includes a P well (P⁻) 12 formed in an N-type silicon substrate (Nsub) 11, an N-type impurity region (N⁻) 13, an N-type impurity region (N⁺) 14, and a P-type impurity region (P⁺) 15 that are formed in the P well 12, a gate insulation film 19 located on the P well 12, and a gate electrode (transfer gate electrode) 20 located on the gate insulation film 19.

The N-type impurity region (N⁻) 13, which is a first impurity region, is located in the P well 12. As viewed in plan view, the N-type impurity region 13 is located at least in a region outside the gate electrode 20 on a first end portion side (the end portion in a gate length direction on the left side of the diagram), and constitutes an N-type impurity region of a photodiode. The expression “as viewed in plan view” as used herein refers to viewing the constituent elements from a direction vertical to a principal surface (upper surface in FIG. 1B) of the N-type silicon substrate 11. Note that the N-type impurity region 13 may extend in the P well 12 under the gate electrode 20 from the first end portion in plan view.

The N-type impurity region (N⁺) 14, which is a second impurity region, is located in the P well 12. As viewed in plan view, the N-type impurity region 14 is at least located in a region outside the gate electrode 20 on a second end portion side (the end portion in the gate length direction on the right side of the diagram) that is opposite to the first end portion of the gate electrode 20. The N-type impurity region 14 is used as an impurity region for storing charges transferred from the photodiode. Note that the N-type impurity region 14 may extend in the P well 12 under the gate electrode 20 from the second end portion as viewed in plan view.

The P-type impurity region (P⁺) 15, which is a third impurity region, is located in an upper portion of the N-type impurity region 14 in the P well 12 and is in contact with the N-type impurity region 14. As viewed in plan view, the P-type impurity region 15 is located separate from the second end portion of the gate electrode 20 in a direction approximately orthogonal to the second end portion (in the gate length direction). The term “upper” as used herein refers to, among directions vertical to the main surface of the N-type silicon substrate 11, a direction extending from the main surface toward the gate electrode 20.

In this way, by providing the P-type impurity region (pinning layer) 15 having a high concentration in an upper portion of the N-type impurity region 14 to which signal charges are transferred from the N-type impurity region 13 that constitutes the photodiode, it is possible to reduce dark current caused by residual charges in the N-type impurity region 14. However, when the pinning layer is provided in the entire upper portion of the N-type impurity region 14, there is a problem in that a potential barrier may be formed in the transfer path for transferring signal charges from the photodiode, causing a transfer failure. According to the present embodiment, since the P-type impurity region 15 is located separate from the second end portion of the gate electrode 20 in the gate length direction, generation of a potential barrier in the transfer path for transferring signal charges can be suppressed and a transfer failure can be reduced.

The characteristic of the solid state imaging element can change according to a distance d between the second end portion of the gate electrode 20 and the P-type impurity region 15 in the gate length direction. For example, in the case where a gate length L0 of the gate electrode 20 shown in FIG. 1 is 3 μm, if the distance d is 0.5 μm or more, the effect of suppressing generation of the potential barrier increases. Here, the distance 0.5 μm corresponds to 1/6 of the gate length 3 μm. Meanwhile, in order to secure a length of 0.5 μm or more by which the N-type impurity region 14 overlaps the P-type impurity region 15 in the gate length direction, the distance d needs to be smaller than the value obtained by subtracting 0.5 μm from a length L1 of the N-type impurity region 14 shown in FIG. 1.

As a result of setting the distance d between the second end portion of the gate electrode 20 and the P-type impurity region 15 in the gate length direction as described above, the generation of a potential barrier in the transfer path for transferring signal charges can be effectively suppressed, and an afterimage phenomenon caused by remaining charges that have not been transferred can be improved, in a range in which dark current caused by residual charges in the N-type impurity region 14 does not increase much.

Manufacturing Method of Solid State Imaging Element

A method of manufacturing the solid state imaging element shown in FIGS. 1A to 1C will be described next.

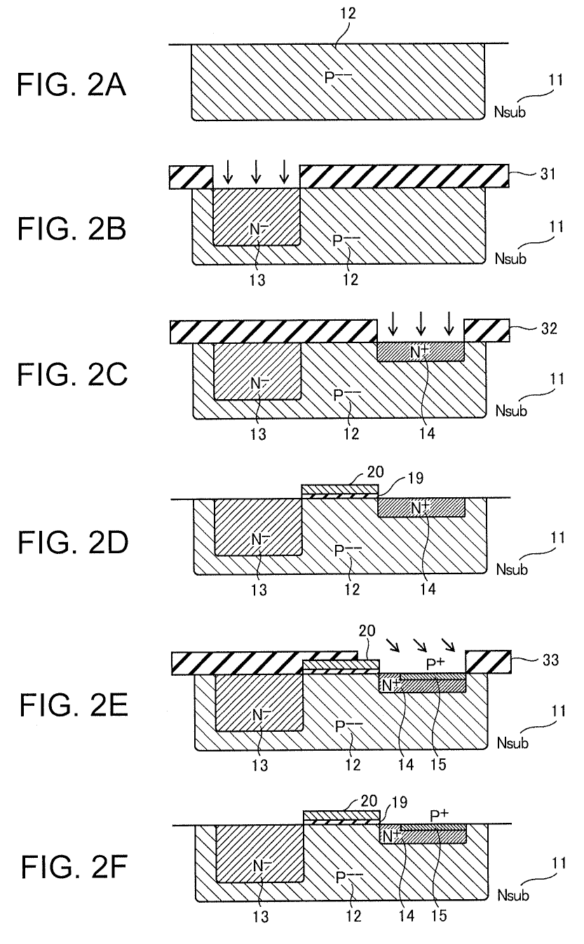

FIGS. 2A to 2F are diagrams illustrating the steps of a method of manufacturing the solid state imaging element shown in FIGS. 1A to 1C. As the semiconductor substrate used to manufacture the solid state imaging element, it is desirable to use an N-type semiconductor substrate having an impurity concentration in the order of 1×10¹⁴ atoms/cm³ or a P-type semiconductor substrate having an impurity concentration of 5×10¹⁴ atoms/cm³ to 5×10¹⁵ atoms/cm³. The following description will be given of, as an example, a case where an N-type silicon substrate 11 (Nsub) having an impurity concentration in the order of 1×10¹⁴ atoms/cm³ is used.

First, a thermal oxide film that serves as a permeable membrane when ion-implantation is performed is formed on a principal surface of the N-type silicon substrate 11. Thereafter, P-type impurity ions such as boron are implanted onto the principal surface of the N-type silicon substrate 11, and the N-type silicon substrate 11 is then heat treated so as to thermally diffuse the impurity ions. A P well (P⁻) 12 is thereby formed in the N-type silicon substrate 11 as shown in FIG. 2A. The P well 12 may be formed by implanting P-type impurity ions in multiple stages (a plurality of times by changing the acceleration energy) or by implanting P-type impurity ions at high energy. It is desirable that the impurity concentration of the P well 12 is, for example, about 1×10¹⁵ atoms/cm³.

Furthermore, on the surface of the N-type silicon substrate 11, an oxide film (not shown), which will serve as an element isolation region is formed by a LOCOS (local oxidation of silicon) method or the like, and a silicon oxide film (not shown), which will serve as a permeable membrane during ion implantation in the next step, is formed.

Next, as shown in FIG. 2B, a photoresist 31 is formed on the N-type silicon substrate 11 by using a photolithography technique. The photoresist 31 has an opening formed in a region that will serve as a photodiode. Furthermore, N-type impurity ions are implanted into the P well 12 by using the photoresist 31 as a mask, and the N-type impurity region (N) 13 constituting the photodiode is formed in the P well 12. At this time, heat treatment may be performed to diffuse impurity ions.

It is desirable that the aforementioned ion implantation is performed by implanting, for example, phosphorus ions in multiple stages at an acceleration energy of about 1.2 MeV to 150 keV so as to form an impurity profile in which the impurity concentration increases from bottom to top of the N-type impurity region 13. It is also desirable that the ion implantation is performed to achieve an impurity concentration of about 1×10¹⁵ atoms/cm³ to 1×10¹⁶ atoms/cm³ so that the N-type impurity region 13 constituting the photodiode is depleted by a depletion layer that will be later formed between the N-type impurity region 13 and the surrounding P-type impurity diffusion layer.

Note that, in FIGS. 1A to 1C, the P well 12 is formed in the N-type silicon substrate 11, and the N-type impurity region 13 is formed in the P well 12. However, it is also possible to form a P-type silicon layer on the N-type silicon substrate 11 by using an epitaxial growth method and then form the N-type impurity region 13 in the P-type silicon layer.

Next, as shown in FIG. 2C, the photoresist 31 is removed, and a photoresist 32 is formed on the N-type silicon substrate 11 by using a photolithography technique. The photoresist 32 has an opening formed in a region that will be a charge transfer destination. Furthermore, N-type impurity ions are implanted into the P well 12 by using the photoresist 32 as a mask, and the N-type impurity region (N⁺) 14 is thereby formed in the P well 12. The impurity concentration of the N-type impurity region 14 is adjusted to be higher than the impurity concentration of the N-type impurity region 13 constituting the photodiode.

The ion implantation is performed by using, for example, arsenic ions or phosphorus ions. In the case where phosphorus ions are used, it is desirable to set the implantation conditions as follows, for example: the acceleration energy is about 100 keV to 150 keV, the dose is about 1×10¹² atoms/cm² to 5×10¹⁴ atoms/cm², and the implantation angle is about 7°.

Next, as shown in FIG. 2D, the photoresist 32 is removed, and the silicon oxide film used as a permeable membrane is removed. After that, a gate insulation oxide film is formed, and polycrystalline silicon or the like is deposited and patterned using a photoresist as a mask. As a result, the gate electrode (transfer gate electrode) 20 is formed on the P well 12 via the gate insulation film 19. The gate electrode 20 includes the first end portion on the N-type impurity region 13 side, and the second end portion on the N-type impurity region 14 side.

At this time, the position of the mask may be adjusted such that the first end portion of the gate electrode 20 coincides with an end portion of the N-type impurity region 13 on the right side in the diagram as viewed in plan view, and the second end portion of the gate electrode 20 coincides with an end portion of the N-type impurity region 14 on the left side in the diagram. Alternatively, the position of the mask may be adjusted such that the gate electrode 20 has an overlapping portion that overlaps the N-type impurity region 13 or 14 as viewed in plan view.

Note that, although the gate insulation film 19 and the gate electrode 20 are formed after the N-type impurity region 14 has been formed in FIGS. 2A to 2F, the N-type impurity region 14 may be formed after the gate insulation film 19 and the gate electrode 20 have been formed. In this case, the gate electrode 20 having the first end portion on the N-type impurity region 13 side is formed on the P well 12 via the gate insulation film 19. Thereafter, N-type impurity ions are implanted into the P well 12 by using the gate electrode 20 and a photoresist as a mask, and the N-type impurity region 14 is thereby formed in the P well 12 in a region outside the gate electrode 20 on the second end portion side as viewed in plan view in a self-aligned manner.

Next, as shown in FIG. 2E, a photoresist 33 is formed, by using a photolithography technique, on the N-type silicon substrate 11 where the gate electrode 20 and the like have been formed. Furthermore, P-type impurity ions are obliquely implanted into the P well 12 by using the gate electrode 20 and the photoresist 33 as a mask, and a P-type impurity region (P⁺) 15 is thereby formed. The P-type impurity region 15, which is a pinning layer, is formed in an upper portion of the N-type impurity region 14 in the P well 12 in a region apart from the second end portion of the gate electrode 20 in a direction approximately orthogonal to the second end portion (gate length direction) in plan view, and is in contact with the N-type impurity region 14. At this time, a P-type impurity region (pinning layer) may be formed in the N-type impurity region 13 as well.

The ion implantation is performed by using boron ions, for example. The impurity concentration of the P-type impurity region 15 is set to, for example, about 1×10¹⁷ atoms/cm³ to 1×10¹⁸ atoms/cm³. It is desirable that the implantation conditions are set as follows when BF²⁺ ions are used, for example: the acceleration energy is about 40 keV, the dose is 5×10¹² atoms/cm² to 5×10¹³ atoms/cm², and the implantation angle is from about 30° to about 45°.

Next, as shown in FIG. 2F, the photoresist 33 is removed. After that, an interlayer insulation film is formed on the N-type silicon substrate 11 where the P-type impurity region 15 and the like have been formed, and a contact hole is formed in the interlayer insulation film. Furthermore, an interconnect layer made of aluminum (Al) or the like is formed on the interlayer insulation film so as to make an interconnection through the contact hole. In this way, a solid state imaging element is obtained. The interconnect layer may be configured as a multilayer if necessary. In addition, it is also possible to simultaneously form a circuit element such as a transistor of a next stage in the N-type silicon substrate 11.

State of Potential

Next, the state of potential in the transfer path for transferring signal charges in the solid state imaging elements according to one embodiment of the invention will be described in comparison with that of a comparative example.

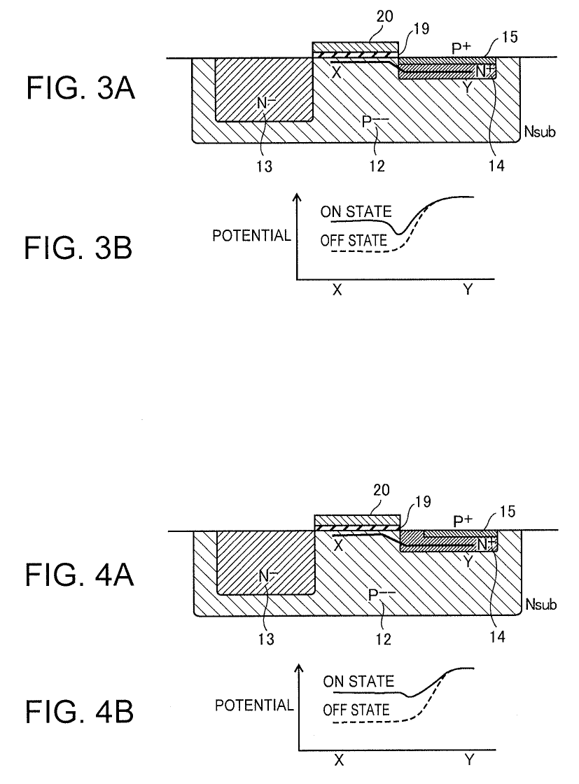

FIGS. 3A and 3B are diagrams schematically showing a solid state imaging element of a comparative example and the state of potential thereof. FIGS. 4A to 4B are diagrams schematically showing the solid state imaging elements according to one embodiment of the invention and the state of potential thereof. Here, FIGS. 3A and 4A are cross-sectional views of the solid state imaging elements. FIGS. 3B and 4B show the state of potential when the transfer gate is turned on (indicated by a solid line) and the state of potential when the transfer gate is turned off (indicated by a broken line) at a position along the line X-Y shown in FIGS. 3A and 4A.

As shown in FIG. 3A, in the comparative example, the N-type impurity region 14 and the P-type impurity region 15 are located in the P well 12 at a position outside the second end portion (the end portion on the right side of the diagram) of the gate electrode 20. In this case, as shown in FIG. 3B, a potential well and barrier are generated at the outlet of the transfer gate, and remaining charges that have not been transferred cause an afterimage phenomenon.

As shown in FIG. 4A, in the embodiment of the invention, the P-type impurity region 15 is located at a position apart from the second end portion (the end portion on the right side of the diagram) of the gate electrode 20 in the gate length direction. In this case, as shown in FIG. 4B, the potential well at the outlet of the transfer gate can become shallow and the potential barrier at the outlet of the transfer gate can be lowered, and thus transfer with less residual charges can be realized.

In this way, according to the present embodiment, as a result of forming the P-type impurity region 15 in an upper region of the N-type impurity region 14 to which signal charges are transferred from the N-type impurity region 13 that constitutes a photodiode, dark current caused by residual charges in the N-type impurity region 14 can be reduced, and, since the P-type impurity region 15 is formed apart from the second end portion of the gate electrode 20 in the gate length direction, generation of a potential barrier in a transfer path for transferring signal charges can be suppressed, and transfer failure can be reduced.

Electronic Apparatus

Next, an electronic apparatus according to one embodiment of the invention will be described.

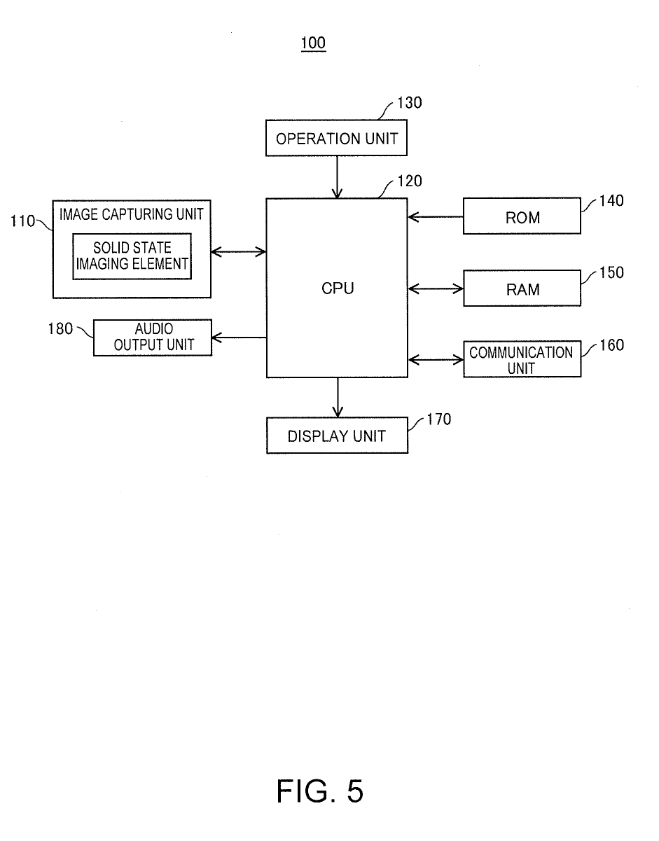

FIG. 5 is a block diagram illustrating an exemplary configuration of the electronic apparatus according to one embodiment of the invention. As shown in FIG. 5, an electronic apparatus 100 includes an image capturing unit 110 using the solid state imaging element according to one embodiment of the invention, and may further include a CPU 120, an operation unit 130, a ROM (read only memory) 140, a RAM (random access memory) 150, a communication unit 160, a display unit 170, and an audio output unit 180. Note that, a portion of the configuration elements shown in FIG. 5 may be omitted or changed, or another configuration element may be added to the configuration elements shown in FIG. 5.

The image capturing unit 110 generates image data by processing pixel signals obtained by capturing an image of a subject using the solid state imaging element according to one embodiment of the invention. For example, the image capturing unit 110 includes the solid state imaging element, a row decoder, a column decoder, an amplifier, a clamp circuit, a CDS (correlated double sampling) circuit, and an ADC (analog/digital converter).

The row decoder sequentially resets a plurality of rows of pixel circuits of the solid state imaging element, and sequentially selects the plurality of rows of pixel circuits. The column decoder sequentially selects pixel signals that are output from a plurality of pixel circuits on a row selected by the row decoder, and sequentially outputs the selected pixel signal. In this way, the pixel signals that are output from the pixel circuits on the selected row and column are supplied to the clamp circuit after being amplified by the amplifier.

The clamp circuit clamps the pixel signal as a black level when an optical black region in which the photodiodes are shielded is scanned in the solid state imaging element. As a result, the amount of increase in the dark current generated due to temperature increase or the like can be cancelled out. The pixel signal output from the clamp circuit is supplied to the CDS circuit.

The pixel signal output from the solid state imaging element includes fixed pattern noise attributed to a characteristic of the pixel circuit. Therefore, the CDS circuit performs CDS processing such that a pixel signal in which the fixed pattern noise is reduced by detecting a difference between levels before and after charges are discharged, by resetting the solid state imaging element. The ADC performs A/D conversion on the pixel signal output from the CDS circuit so as to generate image data.

The CPU 120, in accordance with a program stored in the ROM 140 or the like, performs image processing using image data supplied from the image capturing unit 110 and controls units of the electronic apparatus 100 according to an operation signal supplied from the operation unit 130. For example, the CPU 120 controls the communication unit 160 so as to perform data communication with the outside. Alternatively, the CPU 120 generates an image signal for causing the display unit 170 to display various types of images, and an audio signal for causing the audio output unit 180 to output various types of audio.

The operation unit 130 is an input device that includes an operation key, a button switch, or the like, for example, and outputs an operation signal that corresponds to an operation by an user to the CPU 120. The ROM 140 stores a program, data, or the like for the CPU 120 to perform various types of image processing and control processing. Also, the RAM 150 is used as a work area for the CPU 120, and temporarily stores a program and data read out from the ROM 140, image data supplied from the image capturing unit 110, data that is input using the operation unit 130, a result of arithmetic operation of the CPU 120 according to a program, and the like.

The communication unit 160 is configured by an analog circuit and a digital circuit, for example, and performs data communication between the CPU 120 and the external device. The display unit 170 includes an LCD (liquid crystal display device) or the like, for example, and displays various information based on a display signal supplied from the CPU 120. Also, the audio output unit 180 includes a speaker or the like, and outputs audio based on an audio signal supplied from the CPU 120.

The electronic apparatus 100 is an electronic apparatus that captures an image of a subject and generates image data, such as a drive recorder, a digital movie, a digital still camera, a mobile terminal such as a mobile phone, a TV phone, a security television monitor, a measurement apparatus, or a medical apparatus, and the like, for example.

According to the present embodiment, by using a solid state imaging element in which a dark current caused by residual charges in an impurity region to which signal charges are transferred from a photodiode is reduced, and in addition, a transfer failure is reduced by suppressing the generation of a potential barrier in a transfer path for transferring signal charges, an electronic apparatus in which the quality of image data obtained by capturing a subject is improved can be provided.

The embodiments given above have been described taking a case where an N-type impurity region and the like are formed in a P-type semiconductor layer, but the invention is not limited to the embodiments described above. The invention is also applicable to, for example, a case where a P-type impurity region and the like are formed in an N-type semiconductor layer. Accordingly, various modifications can be made by a person having ordinary skill in the art within the technical scope of the invention.

This application claims priority from Japanese Patent Application No. 2015-178231 filed in the Japanese Patent Office on Sep. 10, 2015 the entire disclosure of which is hereby incorporated by reference in its entirely.

What is claimed is:

1. A solid state imaging element comprising:
a semiconductor layer of a first conductivity type;
a gate insulation film that is located on the semiconductor layer;
a gate electrode that is located on the gate insulation film;
a first impurity region of a second conductivity type that is located in the semiconductor layer and is located, as viewed in plan view, at least in a region outside the gate electrode on a first end portion side;
a second impurity region of the second conductivity type that is located in the semiconductor layer and is located, as viewed in plan view, at least in a region outside the gate electrode on a second end portion side that is opposite to the first end portion of the gate electrode; and
a third impurity region of the first conductivity type that is located on the second impurity region in the semiconductor layer at a position separate from the second end portion of the gate electrode as viewed in plan view.

2. The solid state imaging element according to claim 1,
wherein the third impurity region is, as viewed in plan view, separate from the second end portion of the gate electrode in a direction that is approximately orthogonal to the second end portion by 1/6 or more of a length of the gate electrode.

3. The solid state imaging element according to claim 1,
wherein the first conductivity type is P-type, and the second conductivity type may be N-type.

4. The solid state imaging element according to claim 1,
wherein the first conductivity type is N-type, and the second conductivity type may be P-type.

5. The solid state imaging element according to claim 4,
wherein the semiconductor layer has an impurity concentration in the order of 1×10¹⁴ atoms/cm³.

6. An electronic apparatus comprising the solid state imaging element according to claim 1.

7. A method of manufacturing a solid state imaging element comprising:
(a) implanting impurity ions of a second conductivity type into a semiconductor layer of a first conductivity type by using a first photoresist as a mask so as to form a first impurity region of the second conductivity type in the semiconductor layer;
(b) implanting impurity ions of the second conductivity type into the semiconductor layer by using a second photoresist as a mask so as to form a second impurity region of the second conductivity type in the semiconductor layer;
(c) forming a gate electrode on the semiconductor layer via a gate insulation film, the gate electrode having a first end portion on the first impurity region side and a second end portion on the second impurity region side; and
(d) implanting impurity ions of the first conductivity type obliquely into the semiconductor layer by using the gate electrode and a third photoresist as a mask so as to form a third impurity region of the first conductivity type, the third impurity region being located in an upper portion of the second impurity region in the semiconductor layer at a position separate from the second end portion of the gate electrode as viewed in plan view, and being in contact with the second impurity region.

8. A method of manufacturing a solid state imaging element comprising:
(a) implanting impurity ions of a second conductivity type into a semiconductor layer of a first conductivity type by using a first photoresist as a mask so as to form a first impurity region of the second conductivity type in the semiconductor layer;
(b) forming a gate electrode on the semiconductor layer via a gate insulation film, the gate electrode having a first end portion on the first impurity region side;
(c) implanting impurity ions of the second conductivity type into the semiconductor layer by using the gate electrode and a second photoresist as a mask so as to form a second impurity region of the second conductivity type that is located in the semiconductor layer and is located, as viewed in plan view, in a region outside the gate electrode on a second end portion side that is opposite to the first end portion of the gate electrode; and
(d) implanting impurity ions of the first conductivity type obliquely into the semiconductor layer by using the gate electrode and a third photoresist as a mask so as to form a third impurity region of the first conductivity type, the third impurity region being located in an upper portion of the second impurity region in the semiconductor layer at a position separate from the second end portion of the gate electrode as viewed in plan view, and being in contact with the second impurity region.
